(19) United States
(12) Patent Application Publication
(10) Pub. No.: US 2017/0345667 A1
(43) Pub. Date: Nov. 30, 2017

(54) METHOD OF SILICON EXTRACTION USING A HYDROGEN PLASMA

(71) Applicant: Tokyo Electron Limited, Tokyo (JP)

(72) Inventors: Sonam D. Sherpa, Albany, NY (US); Alok Ranjan, Tomiya-shi (JP)

(21) Appl. No.: 15/607,359

(22) Filed: May 26, 2017

Related U.S. Application Data
(63) Continuation of application No. 62/342,992, filed on May 29, 2016.

(51) Int. Cl. H01L 21/3065

(52) U.S. Cl. CPC H01L 21/3065

(57) ABSTRACT

A method of silicon extraction using a hydrogen plasma has been disclosed in various embodiments. The substrate processing method includes providing a substrate containing a first material consisting of silicon and a second material that is different from the first material, forming a plasma-excited process gas containing H₂ and optionally Ar, and exposing the substrate to the plasma-excited process gas to selectively etch the first material relative to the second material. According to one embodiment, the second material is selected from the group consisting of SiN, SiO₂, and a combination thereof.

### CROSS-REFERENCE TO RELATED APPLICATIONS

This application is related to and claims priority to U. S. Provisional Patent Application serial no. 62/342,992 filed on May 29, 2016, the entire contents of which are herein incorporated by reference.

### FIELD OF INVENTION

The present invention relates to the field of semiconductor manufacturing and semiconductor devices, and more particularly, to a method of silicon extraction using a hydrogen plasma.

### BACKGROUND OF THE INVENTION

Front end of the line etch and patterning processes require extraction of silicon with high or infinite selectivity to the underlying materials. Current methods used to extract silicon involve the redeposition of etch by-products and bombardment by energetic ions. These processes result in footing and significant damage to the underlying material. Therefore, new processing methods for silicon extraction are needed to overcome these problems.

### SUMMARY OF THE INVENTION

Embodiments of the invention describe substrate processing methods using a hydrogen plasma for silicon extraction. Hydrogen plasma can extract silicon with very high selectively to oxide, nitride, and other materials. This process is free of by-product deposition (e.g., polymer) on the substrates and damage to underlying material due to hydrogen ions is negligible.

According to one embodiment, the method includes providing a substrate containing a first material consisting of elemental silicon and a second material that is different from the first material, forming a plasma-excited process gas containing H₂ and optionally Ar, and exposing the substrate to the plasma-excited process gas to selectively etch the first material relative to the second material. In one embodiment, the second material may be selected from the group consisting of SiN, SiO₂, and a combination thereof.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1B schematically show through cross-sectional views a method of processing a substrate;

FIGS. 2A-2B schematically show through cross-sectional views a method of processing a substrate according to an embodiment of the invention;

FIGS. 3A and 3B schematically show through cross-sectional views a method of processing a substrate according to an embodiment of the invention;

FIG. 4 shows experimental results for selective Si etching relative to SiN etching and SiO₂ etching according to an embodiment of the invention;

FIG. 5 shows experimental results for selective Si etching relative to SiN etching and SiO₂ etching according to an embodiment of the invention;

FIGS. 6 and 7 show experimental results for Si etching according to an embodiment of the invention;

FIGS. 8A-8F shows experimental results for selective Si etching relative to SiN etching and SiO₂ etching according to an embodiment of the invention; and

FIG. 9 schematically shows a capacitively coupled plasma (CCP) system according to an embodiment of the invention.

### DETAILED DESCRIPTION OF SEVERAL EMBODIMENTS

Embodiments of the invention describe substrate processing methods using non-polymerizing chemistry to selectively etch elemental silicon (Si) relative to other materials.

As used herein, the notation “SiN” includes layers that contain silicon and nitrogen as the major constituents, where the layers can have a range of Si and N compositions. Si₃N₄ is the most thermodynamically stable of the silicon nitrides and hence the most commercially important of the silicon nitrides. However, embodiments of the invention may be applied to SiN layers having a wide range of Si and N compositions. Furthermore, the notation “SiO₂” is meant to include layers that contain silicon and oxygen as the major constituents, where the layers can have a range of Si and O compositions. SiO₂ is the most thermodynamically stable of the silicon oxides and hence the most commercially important of the silicon oxides.

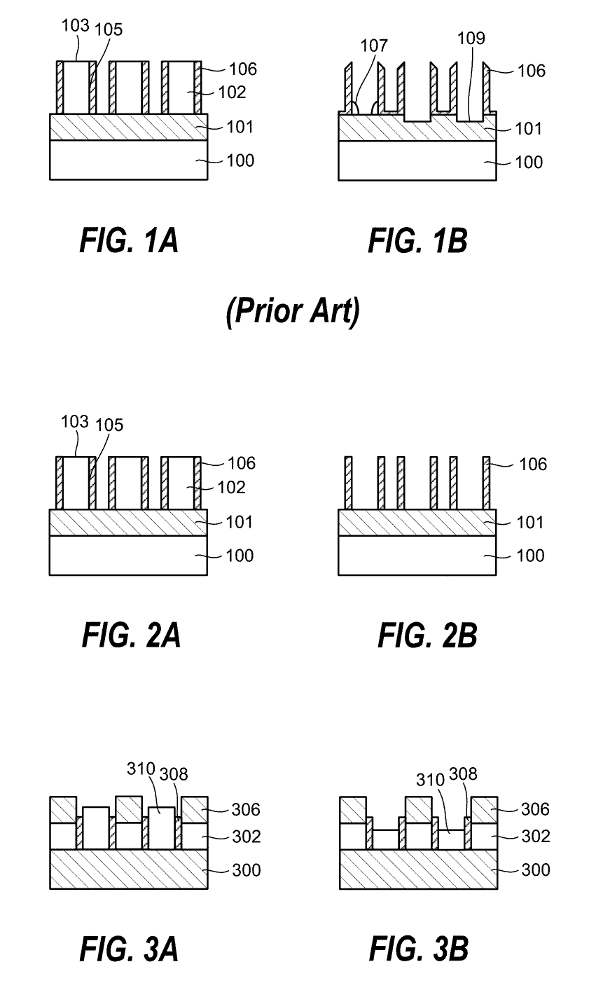

FIGS. 1A and 1B schematically show through cross-sectional views a method of processing a substrate. FIG. 1A shows a substrate 100, a silicon dioxide (SiO₂) layer 101, Si raised features 102, and silicon nitride (SiN) sidewall spacers 106 on the vertical portions 105 of the Si raised features 102. The SiN sidewall spacers 106 may be formed by conformally depositing a SiN spacer layer on horizontal portions 103 and vertical portions 105 of the Si raised features 102, followed by preferentially etching the SiN spacer layer 104 on the horizontal portions 103 in an anisotropic etch process that may include a fluorocarbon-containing plasma. The Si raised features 102 are often referred to as mandrels and they may be removed using a halogen-containing etch process (i.e., a mandrel pull process).

FIG. 1B illustrates several disadvantages of a halogen-containing etch process for removing the Si raised features 102, including oxide (i.e., SiO₂) recess 109 in the SiO₂ layer 101 due to poor etch selectivity between Si and SiO₂, the presence of polymer residue 107, and spacer erosion that produces a tapered profile at the top of the SiN sidewall spacers 106. Embodiments of the invention address these disadvantages of the halogen-containing etch process.

FIGS. 2A and 2B schematically show through cross-sectional views a method of processing a substrate according to an embodiment of the invention. FIG. 1A has been reproduced as FIG. 2A and shows a substrate 100, a SiO₂ layer 101, Si raised features 102, and SiN sidewall spacers 106 on the vertical portions 105 of the Si raised features 102. The Si raised features 102 can contain polycrystalline Si (poly-Si) or amorphous Si (a-Si).

FIG. 2B shows the results of a plasma etch process that selectively removes the Si raised features 102 from the substrate. The plasma etch process includes plasma exciting a process gas containing H₂ and optionally Ar gas, and exposing the structure in FIG. 2A to the plasma-excited process gas. According to one embodiment, the process gas consists of H₂. According to another embodiment, the process gas consists of H₂ and Ar. The resulting structure in FIG. 2B contains SiN sidewall spacers 106 on the SiO₂ layer 101 and it does not have the disadvantages described above and shown in FIG. 1B.

The method described in FIGS. 2A and 2B includes providing a substrate containing a first material that includes raised features on the substrate, a second material that forms sidewall spacers on vertical portions of the raised features, where the first and second materials are in direct contact with an underlying third material, the first material consisting of elemental Si, the second material consisting of SiN, and the third material consisting of SiO₂, forming a plasma-excited process gas consisting of H₂ and optionally Ar, and exposing the substrate to the plasma-excited process gas to selectively remove the first material relative to the second material and the third material.

FIGS. 3A and 3B schematically show through cross-sectional views a method of processing a substrate according to an embodiment of the invention. FIG. 3A shows a structure containing a SiO₂ layer 300, Si layers 302, SiO₂ layers 306, and SiN sidewall spacers 308 bordering exposed Si layers 310.

According to an embodiment of the invention, the structure in FIG. 3A may be processed using an etch process that selectively etches the Si layers 310 relative to the SiO₂ layers 306 and SiN sidewall spacers 308. The etch process includes plasma exciting a process gas containing H₂ and optionally Ar gas, and exposing the structure in FIG. 3A to the plasma-excited process gas. According to one embodiment, the process gas consists of H₂. According to another embodiment, the process gas consists of H₂ and Ar. FIG. 3B shows the structure following the partial Si pull etch process.

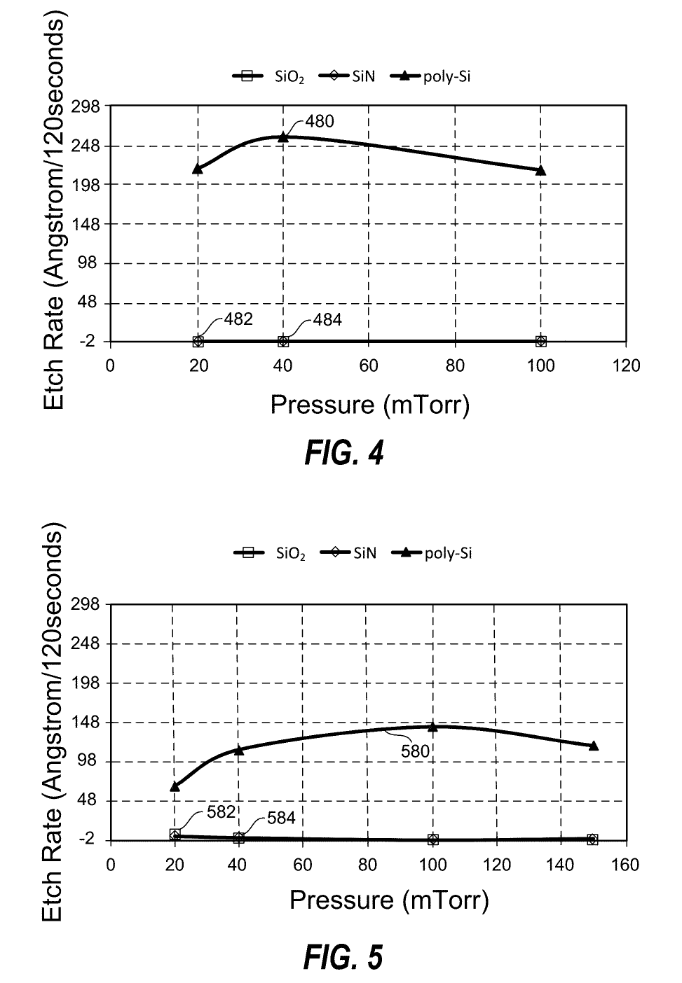

FIG. 4 shows experimental results for selective Si etching 480 relative to SiN etching 482 and SiO₂ etching 484 according to an embodiment of the invention. The plasma etching was performed in a capacitively coupled plasma (CCP) system where processing conditions included upper electrode power of 200 W at 60 MHz, substrate holder temperature of 10° C., and a process gas consisting of H₂ and Ar. The lower electrode was not powered. The chamber pressure was varied from 20-100 mTorr. The etch results show very high etch selectivity for Si etching relative to SiN etching and SiO₂ etching. Under these plasma processing conditions, atomic hydrogen is the dominant etchant species. According to embodiments of the invention, the processing conditions can include an upper electrode power of 200-1000 W at 60 MHz.

FIG. 5 shows experimental results for selective Si etching 580 relative to SiN etching 582 and SiO₂ etching 604 according to an embodiment of the invention. The plasma etching was performed in a CCP system where processing conditions the included lower electrode power of 75 W at 13.56 MHz, substrate holder temperature of 10° C., and a process gas consisting of H₂ and Ar. The upper electrode was not powered. The chamber pressure was varied from 20-150 mTorr. The results show very high etch selectivity for Si etching relative to SiN etching and SiO₂ etching. Under these processing conditions, atomic hydrogen is still the dominant etchant species although the hydrogen ions are energetic with ion energy (Eᵢₒₙ)>sputtering threshold for the substrate. According to embodiments of the invention, the processing conditions can include a lower electrode power of 75-250 W at 13.56 MHz.

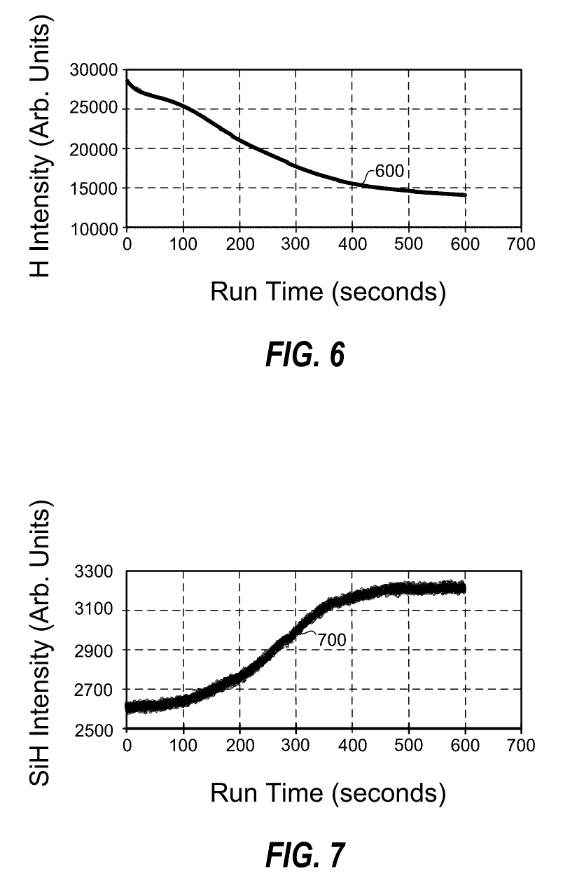

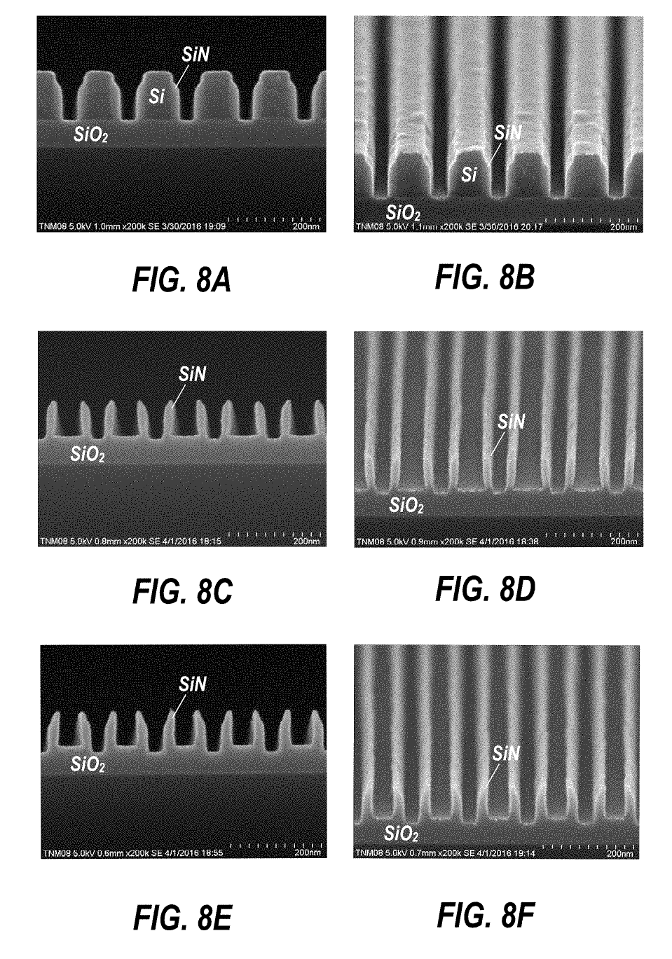

FIGS. 6 and 7 show experimental results for Si etching according to an embodiment of the invention. In FIG. 6, the plot shows H plasma intensity 600 measured at 656.5 nm using optical emission spectroscopy (OES) vs. plasma run time. In FIG. 7, the plot shows SiH plasma intensity 800 measured at 414.0 nm using OES vs. plasma run time. The results in FIGS. 7 and 8 show evidence of chemical etching of silicon by atomic hydrogen. The plasma etching was performed in a CCP system where processing conditions the included upper electrode power of 200W at 60MHz, substrate holder temperature of 10° C., and a process gas consisting of H₂ and Ar. The lower electrode was not powered. The chamber pressure was 20 mTorr. According to embodiments of the invention, the processing conditions can include an upper electrode power of 200-1000 W at 60 MHz, and a chamber pressure of 20-150 mTorr.

FIGS. 8A-8F shows experimental results for selective Si etching relative to SiN etching and SiO₂ etching according to an embodiment of the invention. Cross-sectional scanning electron microscopy (SEM) graphs in FIGS. 8A and 8B show as-received samples containing SiN sidewall spacers on sidewall portions of poly Si raised layers, both overlying a SiO₂ layer.

FIGS. 8C and 8D show SEM graphs following a plasma etch process (mandrel pull) that selectively etches the poly Si raised layers relative to the SiN sidewall spacers and the SiO₂ layer. The plasma etch process was performed using a CCP plasma processing system and processing conditions that included upper electrode power of 200 W at 60 MHz, substrate holder temperature of 10° C., and a process gas consisting of H₂ and Ar. The lower electrode was not powered. The chamber pressure was 20 mTorr. According to embodiments of the invention, the processing conditions can include an upper electrode power of 200-1000 W at 60 MHz, and a chamber pressure of 20-150 mTorr.

FIGS. 8E and 8F show SEM graphs following a plasma etch process (mandrel pull) to form SiN sidewall spacers using a conventional halogen-containing chemistry in a CCP plasma processing system. The processing conditions included upper electrode power of 500 W at 60 MHz, lower electrode power of 100 W at 13.56 MHz, Cl₂ gas flow of 90 sccm, substrate holder temperature of 50° C., and run time of 75 seconds. The chamber pressure was 80 mTorr.

Comparison of the inventive etch process in FIGS. 8C and 8D to the conventional etch process in FIGS. 8E and 8F shows that the inventive etch process does not result in polymer residue, reduces tapering of the SiN sidewall spacers, and reduces oxide recess by high etch selectivity.

According to embodiments of the invention, the process gas may be plasma excited using a variety of different plasma sources. According to one embodiment, the plasma source can include a CCP source that contains an upper plate electrode, and a lower plate electrode supporting the substrate. Radio frequency (RF) power may be provided to the upper plate electrode, the lower plate electrode, or both the upper plate and the lower plate electrode, using RF generators and impedance networks. A typical frequency for the application of RF power to the upper electrode ranges from 10 MHz to 200 MHz and may be 60 MHz. Additionally, a typical frequency for the application of RF power to the lower electrode ranges from 0.1 MHz to 100 MHz and may be 13.56 MHz. A CCP system that may be used to perform the mandrel pull etch process shown in FIGS. 8C and 8D. According to one embodiment, forming the plasma-excited process gas includes generating a plasma using a remote plasma source that creates a high radical to ion flux ratio. The remote plasma source may be located outside of the plasma processing chamber and the plasma-excited gas flowed into the plasma processing chamber to process the substrate.

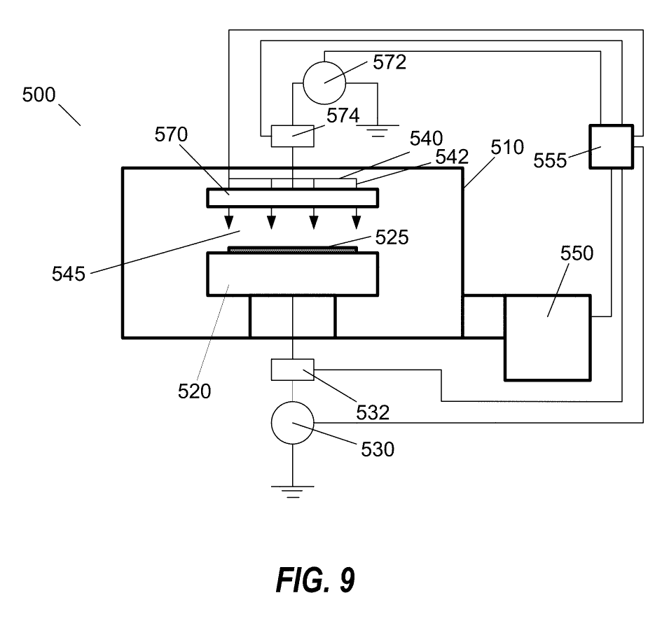

An exemplary plasma processing device 500 depicted in FIG. 9 includes a chamber 510, a substrate holder 520, upon which a substrate 525 to be processed is affixed, a gas injection system 540, and a vacuum pumping system 550. Chamber 510 is configured to facilitate the generation of plasma in a processing region 545 adjacent a surface of substrate 525, wherein plasma is formed via collisions between heated electrons and an ionizable gas. An ionizable gas or mixture of gases is introduced via the gas injection system 540 and the process pressure is adjusted. For example, a gate valve (not shown) is used to throttle the vacuum pumping system 550.

Substrate 525 is transferred into and out of chamber 510 through a slot valve (not shown) and chamber feed-through (not shown) via robotic substrate transfer system where it is received by substrate lift pins (not shown) housed within substrate holder 520 and mechanically translated by devices housed therein. Once the substrate 525 is received from the substrate transfer system, it is lowered to an upper surface of the substrate holder 520.

In an alternate embodiment, the substrate 525 is affixed to the substrate holder 520 via an electrostatic clamp (not shown). Furthermore, the substrate holder 520 further includes a cooling system including a re-circulating coolant flow that receives heat from the substrate holder 520 and transfers heat to a heat exchanger system (not shown), or when heating, transfers heat from the heat exchanger system. Moreover, gas may be delivered to the back-side of the substrate to improve the gas-gap thermal conductance between the substrate 525 and the substrate holder 520. Such a system is utilized when temperature control of the substrate is required at elevated or reduced temperatures. For example, temperature control of the substrate may be useful at temperatures in excess of the steady-state temperature achieved due to a balance of the heat flux delivered to the substrate 525 from the plasma and the heat flux removed from substrate 525 by conduction to the substrate holder 520. In other embodiments, heating elements, such as resistive heating elements, or thermo-electric heaters/coolers are included.

In a first embodiment, the substrate holder 520 further serves as an electrode through which radio frequency (RF) power is coupled to plasma in the processing region 545. For example, the substrate holder 520 is electrically biased at a RF voltage via the transmission of RF power from an RF generator 530 through an impedance match network 532 to the substrate holder 520. The RF bias serves to heat electrons and, thereby, form and maintain plasma. In this configuration, the system operates as a reactive ion etch (ME) reactor, wherein the chamber and upper gas injection electrode serve as ground surfaces. A typical frequency for the RF bias ranges from 0.1 MHz to 100 MHz and may be 13.56 MHz. In an alternate embodiment, RF power is applied to the substrate holder electrode at multiple frequencies. Furthermore, the impedance match network 532 serves to maximize the transfer of RF power to plasma in processing chamber 10 by minimizing the reflected power. Match network topologies (e.g. L-type, π-type, T-type, etc.) and automatic control methods are known in the art.

With continuing reference to FIG. 9, a process gas 542 (e.g., containing H₂ and optionally Ar) is introduced to the processing region 545 through the gas injection system 540. Gas injection system 540 can include a showerhead, wherein the process gas 542 is supplied from a gas delivery system (not shown) to the processing region 545 through a gas injection plenum (not shown), a series of baffle plates (not shown) and a multi-orifice showerhead gas injection plate (not shown).

Vacuum pumping system 550 preferably includes a turbo-molecular vacuum pump (TMP) capable of a pumping speed up to 5000 liters per second (and greater) and a gate valve for throttling the chamber pressure. In conventional plasma processing devices utilized for dry plasma etch, a 1000 to 3000 liter per second TMP is employed. TMPs are useful for low pressure processing, typically less than 50 mTorr. At higher pressures, the TMP pumping speed falls off dramatically. For high pressure processing (i.e. greater than 100 mTorr), a mechanical booster pump and dry roughing pump are used.

A computer 555 includes a microprocessor, a memory, and a digital I/O port capable of generating control voltages sufficient to communicate and activate inputs to the plasma processing system 500 as well as monitor outputs from the plasma processing system 500. Moreover, the computer 555 is coupled to and exchanges information with the RF generator 530, the impedance match network 532, the gas injection system 540 and the vacuum pumping system 550. A program stored in the memory is utilized to activate the inputs to the aforementioned components of a plasma processing system 500 according to a stored process recipe.

The plasma processing system 500 further includes an upper plate electrode 570 to which RF power is coupled from an RF generator 572 through an impedance match network 574. A typical frequency for the application of RF power to the upper electrode ranges from 10 MHz to 200 MHz and is preferably 60 MHz. Additionally, a typical frequency for the application of power to the lower electrode ranges from 0.1 MHz to 30 MHz. Moreover, the computer 555 is coupled to the RF generator 572 and the impedance match network 574 in order to control the application of RF power to the upper plate electrode 570.

A method of silicon extraction using a hydrogen plasma has been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method, comprising:
providing a substrate containing a first material consisting of elemental Si and a second material that is different from the first material;
forming a plasma-excited process gas containing H₂ and optionally Ar; and
exposing the substrate to the plasma-excited process gas to selectively etch the first material relative to the second material.

2. The method of claim 1, wherein the process gas consists of H₂.

3. The method of claim 1, wherein the process gas consists of H₂ and Ar.

4. The method of claim 1, wherein the second material is selected from the group consisting of SiN, SiO₂, and a combination thereof.

5. The method of claim 1, wherein the second material includes an organic material.

6. The method of claim 1, wherein the first material includes raised features on the substrate, the second material forms sidewall spacers on vertical portions of the raised features, and the exposing removes the raised features of the first material but not the sidewall spacers.

7. The method of claim 6, wherein the second material is selected from the group consisting of SiN and SiO₂.

8. The method of claim 6, wherein the first and second materials are direct contact with an underlying SiO₂ material, and the second material includes SiN.

9. The method of claim 1, wherein forming the plasma-excited process gas includes generating a plasma using a capacitively coupled plasma source containing an upper plate electrode, and a lower plate electrode supporting the substrate.

10. The method of claim 1, wherein forming the plasma-excited process gas includes generating a plasma using a remote plasma source that creates a high radical to ion flux ratio.

11. A substrate processing method, comprising:
providing a substrate containing a first material consisting of elemental Si and a second material selected from the group consisting of SiN, SiO₂, and a combination thereof;
forming a plasma-excited process gas consisting of H₂ and Ar; and
exposing the substrate to the plasma-excited process gas to selectively etch the first material relative to the second material.

12. The method of claim 11, wherein the first material includes raised features on the substrate, the second material forms sidewall spacers on the vertical portions of the raised features, and wherein the exposing removes the raised features of the first material but not the sidewall spacers.

13. The method of claim 11, wherein forming the plasma-excited process gas includes generating a plasma using a capacitively coupled plasma source containing an upper plate electrode, and a lower plate electrode supporting the substrate.

14. The method of claim 11, wherein forming the plasma-excited process gas includes generating a plasma using a remote plasma source that creates a high radical to ion flux ratio.

15. A substrate processing method, comprising:
providing a substrate containing a first material that includes raised features on the substrate, a second material that forms sidewall spacers on vertical portions of the raised features, wherein the first and second materials are in direct contact with an underlying third material, the first material consisting of elemental Si, the second material consisting of SiN, and the third material consisting of SiO₂;
forming a plasma-excited process gas consisting of H₂ and optionally Ar; and
exposing the substrate to the plasma-excited process gas to selectively remove the first material relative to the second material and the third material.

16. The method of claim 15, wherein forming the plasma-excited process gas includes generating a plasma using a capacitively coupled plasma source containing an upper plate electrode, and a lower plate electrode supporting the substrate.

17. The method of claim 15, wherein forming the plasma-excited process gas includes generating a plasma using a remote plasma source that creates a high radical to ion flux ratio.

18. The method of claim 15, wherein the process gas consists of H₂.

19. The method of claim 15, wherein the process gas consists of H₂ and Ar.
